(19) United States
(12) Patent Application Publication
(10) Pub. No.: US 2010/0079207 A1
(43) Pub. Date: Apr. 1, 2010

(54) STAGED LINEAR CONVERSION METHOD

(76) Inventor: JY-DER David TAI, Sanchong City (TW)

Correspondence Address: SINORICA, LLC, 2275 Research Blvd., Suite 500, ROCKVILLE, MD, 20850, US

(21) Appl. No.: 12/339,193

(22) Filed: Dec. 19, 2008

(30) Foreign Application Priority Data
Sep. 26, 2008 (TW) 97137079

(51) Int. Cl. H03F 3/217

(52) U.S. Cl. 330/251

(57) ABSTRACT

The present invention discloses a staged linear conversion method, which comprises steps: receiving a staged linear triangular-wave signal and a reference signal with a comparator, wherein the staged linear triangular-wave signal has a waveform having at least three different slopes; and performing a conversion on the reference signal to output a PWM signal according to the voltages of the intersections of the staged linear triangular-wave signal and the reference signal and the slope variation of the staged linear triangular-wave signal. The present invention can reduce the distortion of saturation signals when a Class D amplifier performs signal conversion.

### BACKGROUND OF THE INVENTION

1. Field of the Invention

The present invention relates to a conversion method, particularly to a staged linear conversion method.

2. Description of the Related Art

The conventional audio power amplifiers usually are Class AB type. Recently, Class D power amplifier is growing popular because of the development of IC and the requirement of high conversion efficiency. The power conversion efficiency for normal operation of Class D power amplifier is about 3-5 times that of Class AB power amplifier. However, THD (Total Harmonic Distortion) of Class D power amplifier is greater than that of Class AB power amplifier. When the output signal of a power amplifier is reaching saturation, or when the output peak voltage is approaching the service voltage, THD increases fast with the increasing voltage of the output signal. The present invention is to deal with large-signal THD to achieve an identical output power with a smaller THD or a larger output power with an identical THD.

Refer to FIG. 1 for the circuit of a conventional technology. In the conventional technology, a comparator 5 receives a triangular-wave signal and a reference signal and converts the reference signal to output a PWM (Pulse Width Modulation) signal. Refer to FIGS. 2(a)-2(e) for the waveforms (the voltage-time relationships) of the triangular-wave signal, the reference signal and the PWM signal in the circuit, wherein the triangular-wave signal has only two slopes.

Herein, an analog signal is used to exemplify the reference signal. Refer to FIGS. 2(a) and 2(b). When the voltage of the analog signal is exactly the mean value V₀ of the triangular-wave signal, the duty cycle of the PWM signal is equal to 50%. Refer to FIGS. 2(a) and 2(c). When the voltage of the analog signal is the peak voltage V₁ of the triangular-wave signal, the duty cycle of the PWM signal is almost equal to 100%. Therefore, while the voltage of the analog signal increases from V₀ to V₁, the duty cycle of the PWM signal grows linearly from 50% to 100%. Refer to FIGS. 2(a) and 2(d). When the voltage of the analog signal grows to V₂ a voltage greater than the peak voltage of the triangular-wave signal, the duty cycle of the PWM signal is still equal to 100%. In such a case, the duty cycle cannot be greater than but can only be maintained 100%, and the PWM signal can no more express the voltage of the analog signal. If the PWM signal is converted back to the analog signal in such a case, it will be found that the obtained analog signal is seriously distorted. Refer to FIGS. 2(a) and 2(e). When the voltage of the analog signal decreases to V₃ a voltage lower than the trough voltage of the triangular-wave signal, the duty cycle of the PWM signal is equal to 0%. In such a case, the duty cycle cannot be smaller than but can only be maintained 0%, and the PWM signal can no more express the voltage of the analog signal. If the PWM signal is converted back to the analog signal in such a case, it will be found that the obtained analog signal is seriously distorted. From the above description, it is known that when the voltage of the analog signal is between the peak voltage and the trough voltage of the triangular-wave signal, the PWM signal can faithfully express the voltage of the analog signal. When the voltage of the analog signal is higher than the peak voltage of the triangular-wave signal or lower than the trough voltage of the triangular-wave signal, the PWM signal cannot express the voltage of the analog signal, and THD rises rapidly.

Accordingly, the present invention proposes a staged linear conversion method to overcome the abovementioned problem.

### SUMMARY OF THE INVENTION

The primary objective of the present invention is to provide a staged linear conversion method, wherein a reference signal is converted into a PWM signal according to a triangular-wave signal having different slopes in different voltage ranges, wherefore the present invention can reduce the distortion of saturation signals when a Class D amplifier performs signal conversion.

To achieve the abovementioned objective, the present invention proposes a staged linear conversion method. In the present invention, a comparator receives a staged linear triangular-wave signal and a reference signal, and the staged linear triangular-wave signal has a waveform having at least three different slopes. Next, the comparator performs a PWM conversion on the reference signal to output a PWM signal according to the voltages of the intersections of the staged linear triangular-wave signal and the reference signal and the slopes of the staged linear triangular-wave signal.

Below, the embodiments are described in detailed in cooperation with the drawings to make easily understood the technical contents, characteristics and accomplishments of the present invention.

### BRIEF DESCRIPTION OF THE DRAWINGS

FIG. 1 is a diagram schematically showing the circuit of a conventional technology;

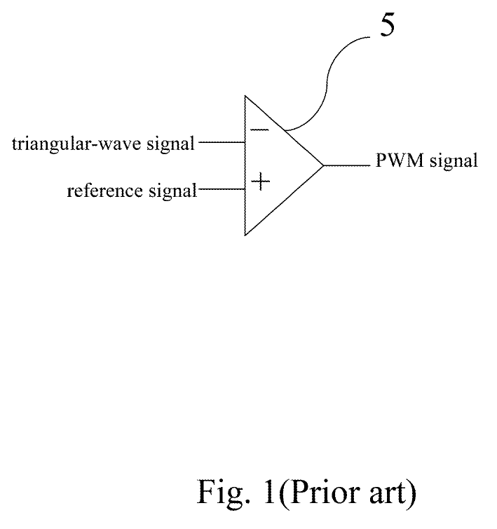

FIG. 2(a) is a diagram schematically showing waveforms of a triangular-wave signal and an analog signal in a conventional technology;

FIGS. 2(b)-2(e) are diagrams schematically showing waveforms of PWM signals in a conventional technology;

FIG. 3 is a diagram schematically showing a circuit according to the present invention;

FIG. 4(a) is a diagram schematically showing waveforms of a staged linear triangular-wave signal and an analog signal according to the present invention;

FIGS. 4(b)-4(e) are diagrams schematically showing waveforms of PWM signals according to the present invention;

FIG. 5 is a diagram schematically showing a circuit for testing the present invention;

FIGS. 6-8 are diagrams schematically showing the waveforms obtained in the experiments for the conventional technology and the present invention;

FIG. 9 is a partially enlarged view of the waveforms of the filtered sinusoidal signals in FIG. 7 and FIG. 8; and

FIG. 10 is a diagram showing the waveforms of the original sinusoidal signal, the staged linear triangular-wave signal, the PWM signal and the filtered sinusoidal signal experimentally obtained according to the present invention.

### DETAILED DESCRIPTION OF THE INVENTION

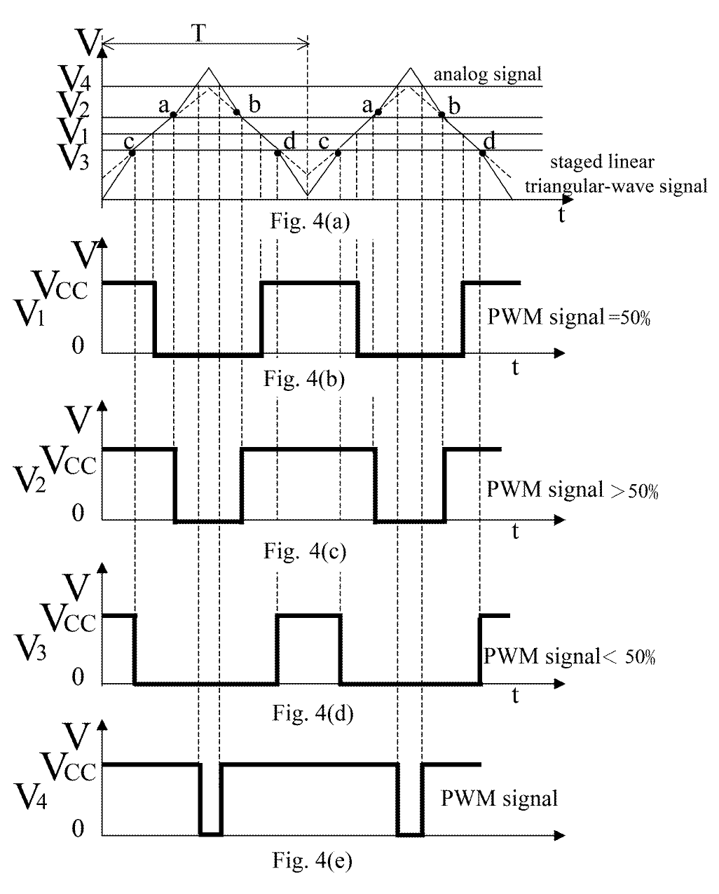

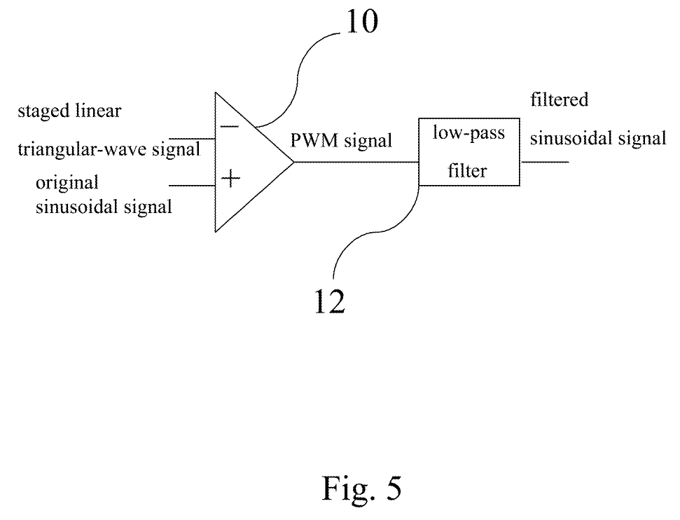

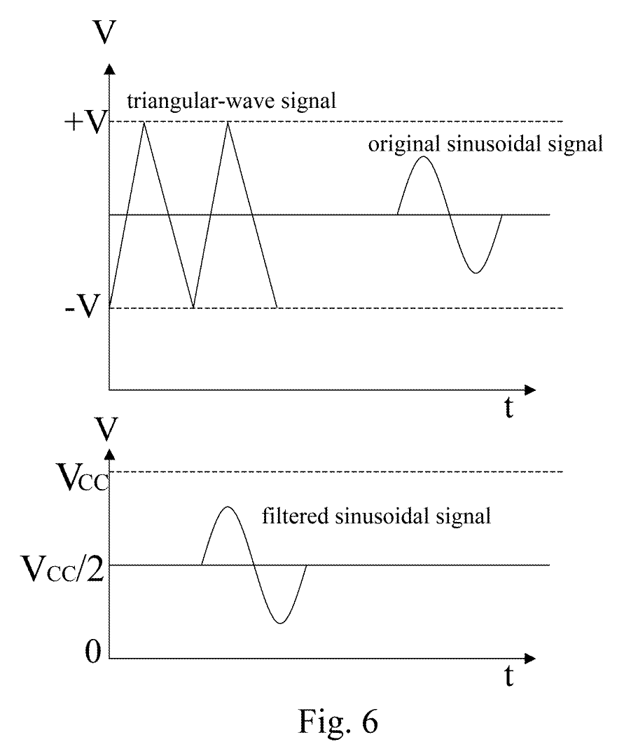

Refer to FIG. 3. The present invention uses a comparator 10 to receive a staged linear triangular-wave signal at the negative input terminal and a reference signal at the positive input terminal. The reference signal may be a sinusoidal signal or an analog signal. Each wave of the staged linear triangular-wave signal contains at least three segments respectively having three different slopes. For example, each wave of the staged linear triangular-wave signal shown in FIG. 4(a) contains six segments respectively have six different slopes. According to the voltages of the intersections of the reference signal and the triangular-wave signal and the slope variation of the triangular-wave signal, a PWM conversion is performed on the reference to output a PWM signal.

Herein, an analog signal is used to exemplify the reference signal. FIGS. 4(a)-4(e) are diagrams showing the waveforms (the voltage-time relationships) of the triangular-wave signal, the reference signal and the PWM signal in the circuit. Refer to FIGS. 4(a) and 4(b). The triangular wave shown in FIG. 4(a) contains six segments respectively having six different slopes, and the segments near the peak or trough of the wave have the slopes with the absolute values greater than those of the other segments. Points a, b, c and d represent the voltages at the inflection points of the slopes. When the time interval between two time points of the intersections of the analog signal and one wave of the triangular-wave signal is equal to half the cycle (T/2) of the triangular-wave signal, or when the voltage of the analog signal is equal to V₁, the duty cycle of the PWM signal is 50%.

FIGS. 4(a) and 4(c). When the time interval between two time points of the intersections of the analog signal and one wave of the triangular-wave signal is smaller than half the cycle (T/2) of the triangular-wave signal, or when the voltage of the analog signal is equal to V₂, the duty cycle of the PWM signal is greater than 50%.

FIGS. 4(a) and 4(d). When the time interval between two time points of the intersections of the analog signal and one wave of the triangular-wave signal is greater than half the cycle (T/2) of the triangular-wave signal, or when the voltage of the analog signal is equal to V₃, the duty cycle of the PWM signal is smaller than 50%.

From the above description, it is known that the duty cycle of the PWM signal varies with the time interval between two time points of the intersections of the analog signal and one wave of the triangular-wave signal. In the region of an identical slope, the extent of the pulse width modulation varies linearly with the voltage of the analog signal.

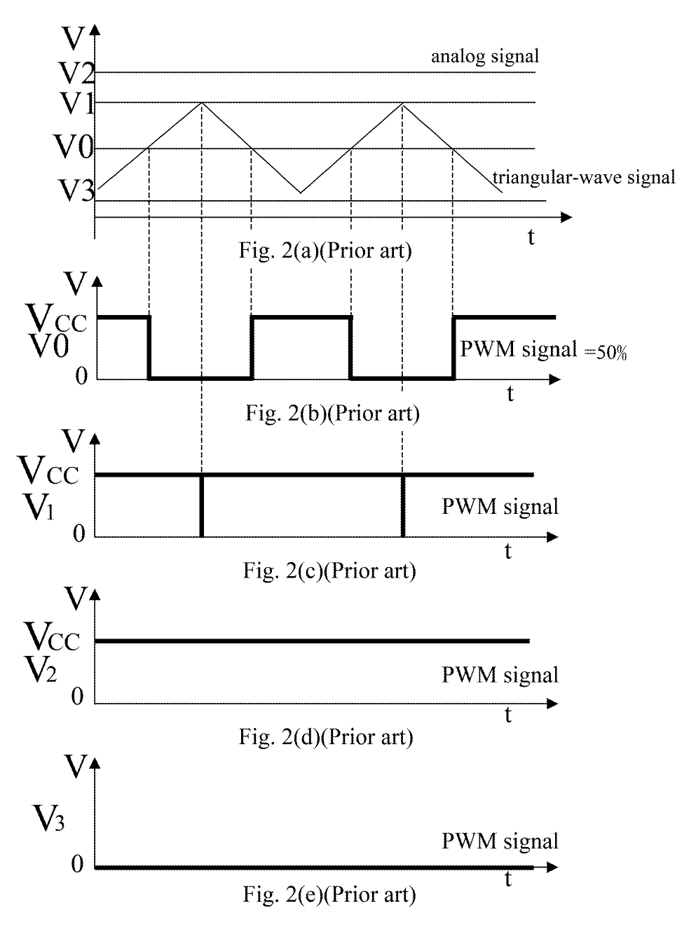

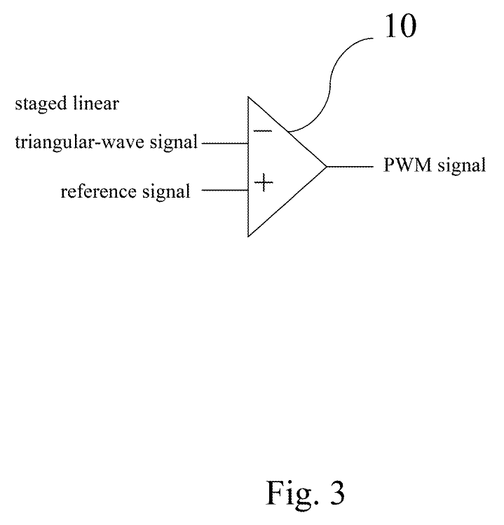

FIGS. 4(a) and 4(e). When the voltage of the analog signal is equal to V₄, the voltage of the analog signal is within a higher-slope region but still below the peak voltage of the triangular-wave signal. As the slope is greater in this region, the pulse width varies less fast in the higher-slope region than in other regions with respect to the voltage variation of the analog signal. From the above description, it is known that the rate of the pulse width variation is dependent on the voltage of the analog signal. When the voltage of the analog signal is higher and within a higher-slope region, the rate of the pulse width variation with respect to the voltage variation of the analog signal is smaller. When the voltage of the analog signal is lower and within another higher-slope region of the staged linear triangular wave, the rate of the pulse width variation with respect to the voltage variation of the analog signal is also smaller. In the time when the voltage of the analog signal is within a higher-slope region, the PWM signal is not necessarily a high level output. In other words, the PWM signal does not stand at the saturation state but still varies with the voltage of the analog signal. The voltage V₄ of the analog signal in FIG. 4(e) is equivalent to the voltage V₁ of the analog signal in FIG. 2(a). The duty cycle of the PWM signal for the analog signal having a voltage V₁ is almost equal to 1 in the conventional technology. For the staged linear triangular-wave signal, the duty cycle does not approach 1 so fast because of the higher-slope region near the peak voltage. Such a phenomenon also occurs in the higher-slope region near the trough voltage of the staged linear triangular-wave signal.

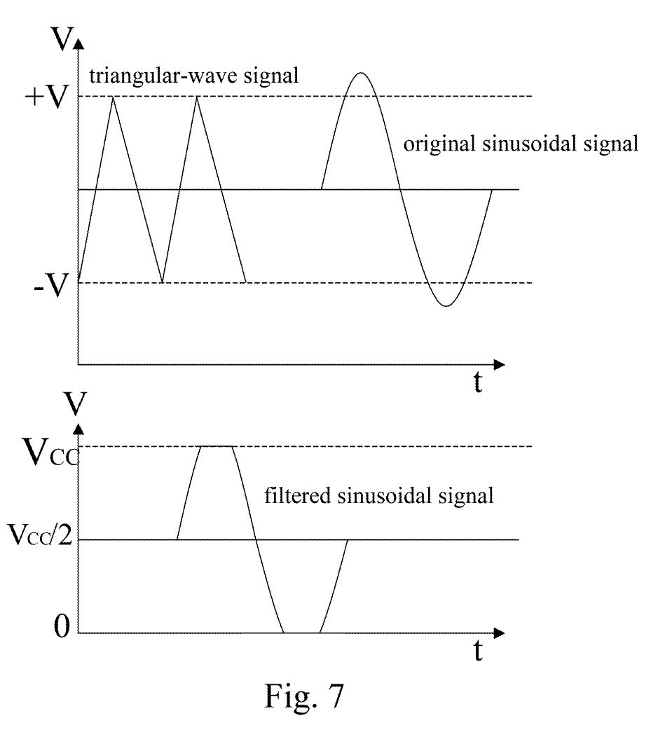

Refer to FIG. 5. Herein, a sinusoidal signal is used to exemplify the reference signal. The present invention uses a comparator 10 to receive a staged linear triangular-wave signal and a sinusoidal signal and then output a PWM signal. A low-pass filter 12 filters out unwanted signals from the PWM signal to obtain a filtered sinusoidal signal.

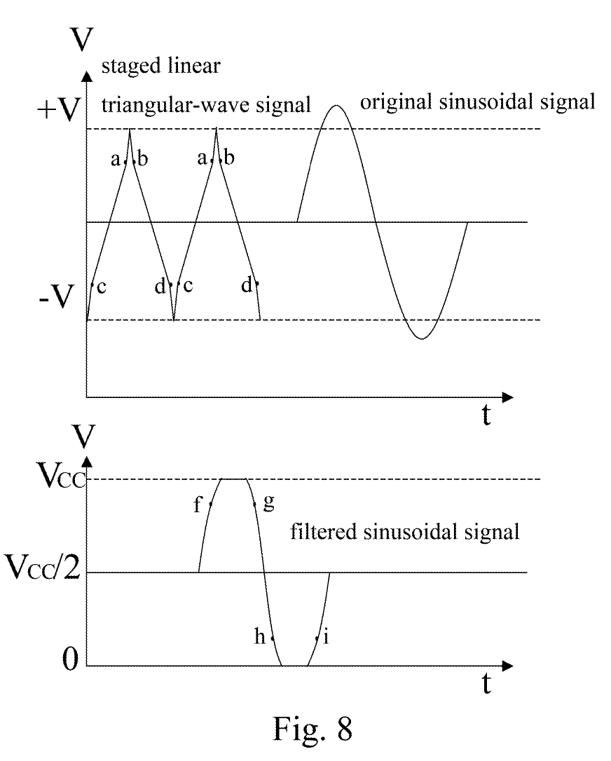

FIGS. 6-8 are diagrams showing the waveforms of the triangular-wave signal, the original sinusoidal signal and the filtered sinusoidal signal. In FIG. 6, the triangular wave has only two slopes, and the original sinusoidal signal has a normal amplitude. In other words, the amplitude of the original sinusoidal signal does not exceed the upper and lower limits of the triangular-wave signal. The filtered sinusoidal signal also has a normal amplitude without distortion.

In FIG. 7, the triangular wave has only two slopes too, but the amplitude of the original sinusoidal signal exceeds the upper and lower limits of the triangular-wave signal. The peaks of the filtered sinusoidal signal are cut off from a voltage Vcc and a zero voltage, which results in a serious distortion.

In FIG. 8, the triangular wave has six segments respectively having six slopes, and the segments near the upper and lower limits have greater slopes than the other segments. The amplitude of the original sinusoidal signal exceeds the upper and lower limits of the triangular-wave signal, and the peaks of the filtered sinusoidal signal are slightly cut off. However, the shape of the waveform near the cut-off regions in FIG. 8 is different from that in FIG. 7. The filtered sinusoidal signal has four points respectively designated by f, g, h, and i. In the positive semi-cycle, the curve of the waveform rises from a voltage of Vcc/2. When the curve passes through Point f, the speed of rising becomes slower because of the slope variation in the triangular-wave signal. Such a case also occurs in the negative semi-cycle.

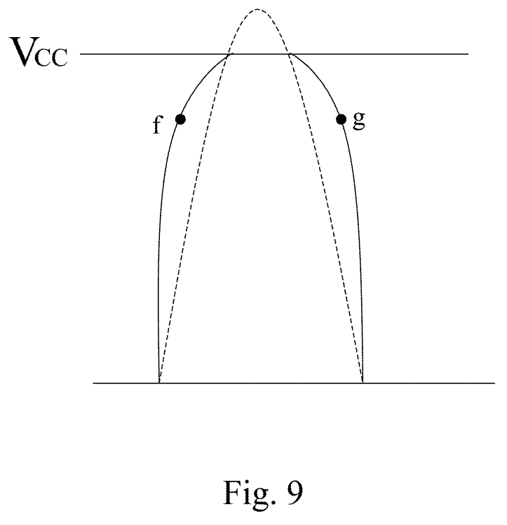

Refer to FIG. 9, wherein the solid curve is the enlarged view of the upper portion of the waveform of the filtered sinusoidal signal in FIG. 8, and the dotted curve is the enlarged view of the upper portion of the waveform of the filtered sinusoidal signal in FIG. 7. For the waveforms between the peaks and Points f and g, the dotted curve rises faster than the solid curve. As the output power is proportional to the area of the waveform, the solid-curve waveform has higher output power. For the waveforms in FIG. 9, the distortions thereof originate from the same fact that the peaks of the filtered sinusoidal signal are cut off from a voltage Vcc and a zero voltage. However, the output power of the waveform generated by a staged linear conversion is greater than that not generated by a staged linear conversion.

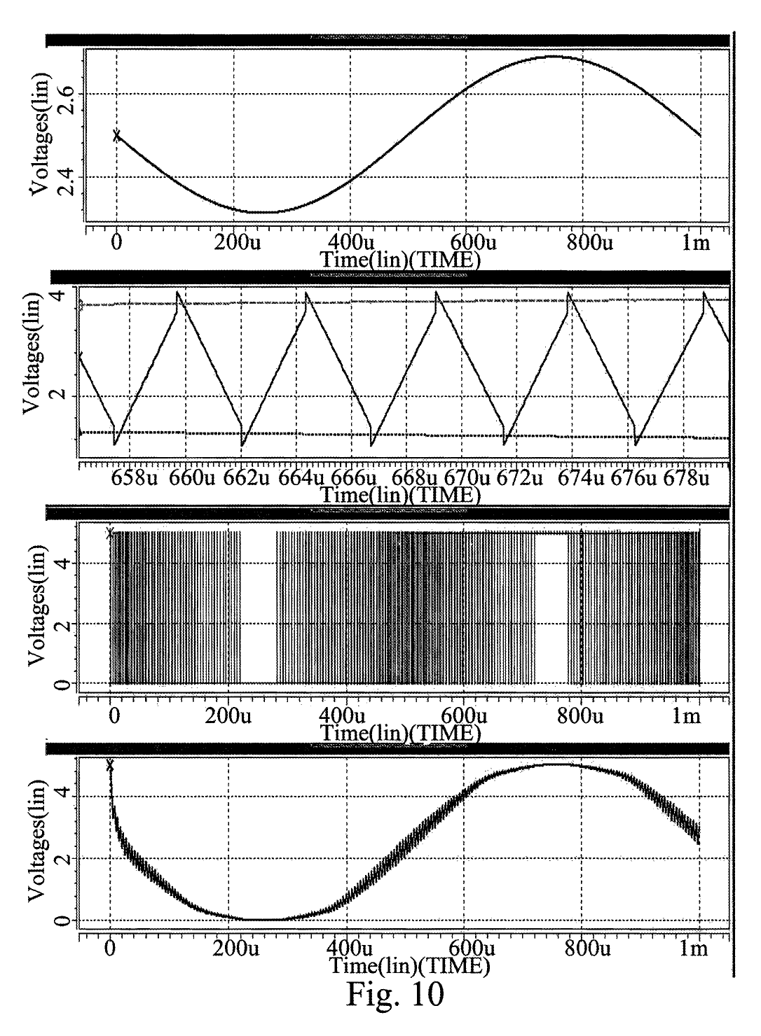

Refer to FIG. 10 a diagram showing the waveforms experimentally obtained with the circuit in FIG. 5. From top to bottom are sequentially shown the waveforms of the original sinusoidal signal, the staged linear triangular-wave signal, the PWM signal, and the filtered sinusoidal signal. The triangular wave has four segments respectively having four different slopes, and the segments near the peak and trough have greater slopes. Therefore, the waveform of the filtered sinusoidal signal rises or descends more slowly in near the peak or trough. Thereby, the high-order harmonic waves are decreased, and distortion is improved. Then is reduced the discomfort of the ears, which is caused by the distorted sound.

In conclusion, the present invention can reduce signal distortion when a Class D amplifier performs signal conversion.

The embodiments described above are only to exemplify the present invention but not to limit the scope of the present invention. Therefore, any equivalent modification or variation according to the shapes, structures, characteristics and spirit disclosed in the present invention is to be also included within the scope of the present invention.

What is claimed is:

1. A staged linear conversion method comprising steps:
receiving a staged linear triangular-wave signal and a reference signal, wherein said staged linear triangular-wave signal has a waveform having at least three different slopes; and
performing an analog-pulse width conversion on said reference signal to output a pulse-width-modulation signal according to voltages of intersections of said staged linear triangular-wave signal and said reference signal and slope variation of said staged linear triangular-wave signal.

2. The staged linear conversion method according to claim 1, wherein in each wave of said staged linear triangular-wave signal, an absolute value of a slope in near a peak or a trough is greater than that in other regions of said wave.

3. The staged linear conversion method according to claim 1, wherein said reference signal is a sinusoidal signal or an analog signal.

4. The staged linear conversion method according to claim 1, wherein a comparator receives said staged linear triangular-wave signal and said reference signal and outputs said pulse-width-modulation signal.

5. The staged linear conversion method according to claim 1, wherein when a time interval between two time points of said intersections of said staged linear triangular-wave signal and said reference signal is equal to half a cycle of said staged linear triangular-wave signal, a duty cycle of said pulse-width-modulation signal is equal to 50%.

6. The staged linear conversion method according to claim 1, wherein pulse width of said pulse-width-modulation signal varies with voltage of said reference signal.

7. The staged linear conversion method according to claim 6, wherein a rate of pulse width variation of said pulse-width-modulation signal depends on a voltage range whereat said reference signal appears.

8. The staged linear conversion method according to claim 7, wherein when said voltage range is at a higher voltage level, said rate of pulse width variation of said pulse-width-modulation signal becomes smaller with respect to voltage variation of said reference signal.

9. The staged linear conversion method according to claim 7, wherein when said voltage range is at a lower voltage level, said rate of pulse width variation of said pulse-width-modulation signal becomes smaller with respect to voltage variation of said reference signal.
